(19) United States
(12) Patent Application Publication
(10) Pub. No.: US 2007/0181873 A1
(43) Pub. Date: Aug. 9, 2007

(54) Organic-inorganic hybrid polymer and organic insulator composition having the same and methods thereof

(76) Inventors: Hyun Sik Moon, Seoul (KR); Eun Jeong Jeong, Seongnam-si (KR); Eun Kyung Lee, Seoul (KR); Sang Yoon Lee, Seoul (KR); Jung Han Shin, Yongin-si (KR); Kyung Seok Son, Seoul (KR)

Correspondence Address: HARNESS, DICKEY & PIERCE, P.L.C., P.O. BOX 8910, RESTON, VA, 20195, US

(21) Appl. No.: 11/581,112

(22) Filed: Oct. 16, 2006

(30) Foreign Application Priority Data
Feb. 4, 2006 (KR) 10-2006-0010894

(51) Int. Cl. H01L 29/08

(52) U.S. Cl. 257/40

(57) ABSTRACT

Example embodiments of the present invention relate to an organic-inorganic hybrid polymer having capped terminal hydroxyl groups and an organic insulator composition including the hybrid polymer and methods thereof. The organic-inorganic hybrid polymer may be prepared by capping terminal hydroxyl groups of silanol moieties that do not participate in the formation of an intermolecular network in an organic-inorganic hybrid material, with an organosilane compound. The organic-inorganic hybrid polymer may increase the hysteresis and physical properties of an organic thin film transistor. The organic-inorganic hybrid polymer may be more effectively utilized in the manufacture of liquid crystal displays (LCDs).

### PRIORITY STATEMENT

This non-provisional application claims the benefit of priority under 35 U.S.C. § 119 on Korean Patent Application No. 10-2006-0010894, filed on Feb. 4, 2006 in the Korean Intellectual Property Office, the entire contents of which are herein incorporated by reference in their entirety.

### BACKGROUND OF THE INVENTION

1. Field of the Invention

Example embodiments of the present invention relate to an organic-inorganic hybrid polymer having capped terminal hydroxyl groups and an organic insulator composition including the hybrid polymer and methods thereof. Other example embodiments relate to an organic-inorganic hybrid polymer prepared by capping terminal hydroxyl groups of silanol moieties that do not contribute to the formation of an intermolecular network in an organic-inorganic hybrid material, increasing the hysteresis of an organic thin film transistor while maintaining the driving characteristics of the organic thin film transistor. Other example embodiments relate to an organic insulator composition including the same.

2. Description of the Related Art

Thin film transistors (TFTs) currently used in displays may include an amorphous silicon semiconductor, a silicon oxide insulating film and/or metal electrodes.

With recent developments in organic semiconductor materials, organic thin film transistors (TFTs) using the organic semiconductor materials have been developed. Organic thin film transistors have been widely researched due to their applicability to new configurations. Organic thin film transistors may have an economical advantage in that organic thin film transistors may be fabricated by printing processes at ambient pressure or roll-to-roll processes using plastic substrates, instead of conventional silicon processes (e.g., plasma-enhanced chemical vapor deposition (CVD)).

Organic semiconductor materials for channel layers of organic thin film transistors (OTFTs) may be categorized as low-molecular weight oligomeric materials or high-molecular weight oligomeric materials. Low-molecular weight oligomeric materials may include melocyanines, phthalocyanines, perylenes, pentacenes, thiophenes, oligothiophenes and the like. The conventional art acknowledges that devices using a pentacene thin film may have a higher charge carrier mobility of about 3.2 to 5.0 cm²/Vs. Devices using an oligothiophene derivative may have a relatively higher charge carrier mobility of about 0.01-0.1 cm²/Vs and a relatively higher on/off current ratio (Iₒₙ/I_{off} ratio). The conventional art devices may depend on vacuum processes for the formation of thin films.

A number of organic thin film transistors (OTFTs) using thiophene-based polymers as high-molecular weight materials have been acknowledged by the conventional art. Although devices using high-molecular weight materials may exhibit poorer device characteristics compared to devices using low-molecular weight materials, high-molecular weight materials may be processed in a larger area at lower costs by solution processes (e.g., printing). The fabrication and testing of high-molecular weight-based organic thin film transistors (e.g., transistors including a charge carrier mobility of 0.01-0.02 cm²/Vs) using a polythiophene-based material (F₈T₂) is acknowledged by the conventional art. The conventional art also acknowledges the fabrication of organic thin film transistors (e.g., transistor including a charge carrier mobility of 0.01-0.04 cm²/Vs) using a regioregular polythiophene (P₃HT). These organic thin film transistors using high-molecular weight materials may have poorer TFT device characteristics (e.g., low charge carrier mobility) compared to organic thin film transistors using pentacene as a low-molecular weight material. The organic thin film transistors using high-molecular weight materials may be fabricated at lower costs without (or minimal) need for higher operating frequency.

Like the aforementioned organic semiconductor materials for channel layers, studies on materials for solution-processible insulating films may be required in order to fabricate flexible organic thin film transistors at a lower cost. There have been a number of attempts to increase the performance of organic thin film transistors. In an attempt to decrease threshold voltage, high-dielectric constant insulators such as ferroelectric insulators (e.g., BaₓSr₁₋ₓTiO₃ (barium strontium titanate) (BST), Ta₂O₅, Y₂O₃, TiO₂, etc.) and inorganic insulators (e.g., PbZrₓTi₁₋ₓO₃ (PZT), Bi₄Ti₃O₁₂, BaMgF₄, SrBi₂(Ta₁₋ₓNbₓ)₂O₉, Ba(Zr₁₋ₓTiₓ)O₃ (BZT), BaTiO₃, SrTiO₃, Bi₄Ti₃O₁₂, etc.) may be used as materials for inorganic insulating films. Some pentacenes may be used as materials for active layers to fabricate organic thin film transistors. The inorganic oxide materials may be comparable to conventional silicon materials in terms of processing.

As the application of OTFTs has expanded beyond liquid crystal displays to include driving devices of flexible displays using organic EL elements, the OTFTs may be required to have a charge carrier mobility of 10 cm²/Vs or higher. Because the OTFTs include organic insulating films having a dielectric constant of about 3 to about 4, the OTFTs may a higher driving voltage of about 30V-50V and/or a threshold voltage of approximately 15V-20V.

Because solution processes enable the fabrication of large-area displays at lower costs, high-molecular weight insulators may be used as gate insulator materials. The formation of high-molecular weight insulators having a higher leakage current in thicker films may result in an increase in driving voltage. It may be necessary to form high-molecular weight insulators into thin films having a lower leakage current and/or a higher capacitance. When electrodes and/or organic semiconductors (OSCs) are produced using high-molecular weight insulators by a solution or printing process, the high-molecular weight insulators may have increased chemical resistance against acids and bases such that the high-molecular weight insulator may not dissolved in solvents to be used.

A larger difference between voltages necessary to obtain a desired Iₒₙ and I_{off} may necessitate the use of a higher voltage to drive an LCD or OLED, causing an increase in consumption of electric power when applied to displays and/or deteriorating the stability of the devices. When a hysteresis is generated, a higher switching speed may not be achieved. As such, after images may remain on displays.

### SUMMARY OF THE INVENTION

Example embodiments of the present invention relate to an organic-inorganic hybrid polymer having capped terminal hydroxyl groups and an organic insulator composition including the hybrid polymer and methods thereof. Other example embodiments relate to an organic-inorganic hybrid polymer prepared by capping terminal hydroxyl groups of silanol moieties that do not contribute to the formation of an intermolecular network in an organic-inorganic hybrid material, increasing the hysteresis of an organic thin film transistor while maintaining the driving characteristics of the organic thin film transistor. Other example embodiments relate to an organic insulator composition having the same.

Example embodiments of the present invention provide an organic-inorganic hybrid polymer for an organic insulator that increases the hysteresis and threshold voltage of an organic thin film transistor while maintaining the charge carrier mobility of the organic thin film transistor.

Other example embodiments of the present invention provide an organic insulator composition including the organic-inorganic hybrid polymer.

In accordance with other example embodiments of the present invention, there is provided an organic-inorganic hybrid polymer prepared by capping terminal hydroxyl groups of an organic-inorganic hybrid material, which is a hydrolysis and condensation product of an organosilane compound, with a compound represented by any one of Formulae 1 to 3 below:

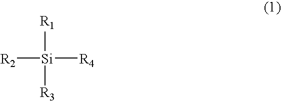

wherein R₁, R₂, R₃ and R₄ are each independently selected from the group including a hydrogen atom; a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups, and substituted and unsubstituted C₆-C₂₀ aryloxy groups, with the proviso that at least one of R₁, R₂, R₃ and R₄ is a hydrolysable functional group;

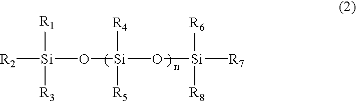

wherein R₁, R₂, R₃, R₄, R₅, R₆, R₇ and R₈ are each independently selected from the group including a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups, and substituted and unsubstituted C₆-C₂₀ aryloxy groups, with the proviso that at least one of R₁, R₂, R₃, R₄, R₅, R₆, R₇ and R₈ is a hydrolysable functional group, and n is an integer from 0 to 50; and

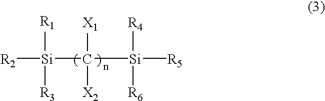

wherein R₁, R₂, R₃, R₄, R₅ and R₆ are each independently selected from the group including a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups, and substituted and unsubstituted C₆-C₂₀ aryloxy groups, with the proviso that at least one of R₁, R₂, R₃, R₄, R₅ and R₆ is a hydrolysable functional group, X₁ and X₂ are each independently selected from the group including a halogen atom, substituted and unsubstituted C₁-C₂₀ alkoxy groups, and substituted and unsubstituted C₆-C₂₀ aryloxy groups, and n is an integer from 0 to 50.

In accordance with yet other example embodiments of the present invention, there is provided an organic insulator composition including the organic-inorganic hybrid polymer, an organometallic compound and/or an organic solvent.

In accordance with other example embodiments of the present invention, there is provided an organic thin film transistor including a substrate, a gate electrode, an organic insulating layer, an organic semiconductor layer and/or source/drain electrodes wherein the organic insulating layer may be formed of the organic insulator composition.

Other example embodiments relate to a method of synthesizing the organic-inorganic hybrid polymer including capping terminal hydroxyl groups of an organic-inorganic hybrid material, wherein the organic-inorganic hybrid material is formed by hydrolyzing and condensing an organosilane compound derivative with the compound represented by any one of Formulae 1 to 3.

In other example embodiments relate to a method of manufacturing the organic insulator composition including forming the organic-inorganic hybrid polymer as described above; and mixing the organic-inorganic hybrid polymer with an organometallic compound and a solvent.

Example embodiments of the present invention also relate to a method of the organic thin film transistor including forming a substrate; forming a gate electrode on the substrate; forming an organic insulating layer coating the gate electrode, wherein the organic insulating layer is formed using the organic insulator composition described above; annealing the organic insulating layer; forming an organic semiconductor layer on the organic insulating layer; and forming source/drain electrodes on the organic insulating layer.

### BRIEF DESCRIPTION OF THE DRAWINGS

Example embodiments of the present invention will be more clearly understood from the following detailed description taken in conjunction with the accompanying drawings. FIGS. 1-7 represent non-limiting, example embodiments of the present invention as described herein.

FIG. 1 is a diagram illustrating a cross-sectional view of an organic thin film transistor according to example embodiments of the present invention;

FIG. 2 is a ¹H-NMR spectrum of an organic-inorganic hybrid polymer prepared prior to capping in Preparative Example 1 according to example embodiments of the present invention;

FIG. 3 is a ¹H-NMR spectrum of an organic-inorganic hybrid polymer prepared after capping in Preparative Example 1 according to example embodiments of the present invention;

FIG. 4 is a ²⁹Si-NMR spectrum of an organic-inorganic hybrid polymer prepared prior to capping in Preparative Example 1 according to example embodiments of the present invention;

FIG. 5 is a ²⁹ Si-NMR spectrum of an organic-inorganic hybrid polymer prepared after capping in Preparative Example 1 according to example embodiments of the present invention;

FIG. 6 is a graph showing the current transfer characteristics of an organic thin film transistor fabricated in Comparative Example 1 as a function of gate voltage according to example embodiments of the present invention; and

FIG. 7 is a graph showing the current transfer characteristics of an organic thin film transistor fabricated in Comparative Example 1 as a function of gate voltage according to example embodiments of the present invention.

### DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only example embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to example embodiments described.

Example embodiments of the present invention relate to an organic-inorganic hybrid polymer having capped terminal hydroxyl groups and an organic insulator composition including the hybrid polymer and methods thereof. Other example embodiments relate to an organic-inorganic hybrid polymer prepared by capping terminal hydroxyl groups of silanol moieties that do not contribute to the formation of an intermolecular network in an organic-inorganic hybrid material, increasing the hysteresis of an organic thin film transistor while maintaining the driving characteristics of the organic thin film transistor. Other example embodiments relate to an organic insulator composition having the same.

Example embodiments of the present invention are directed to an organic-inorganic hybrid polymer prepared by capping terminal hydroxyl groups of an organic-inorganic hybrid material, which is a hydrolysis and condensation product of an organosilane compound, with a compound represented by any one of Formulae 1 to 3 below:

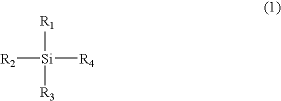

wherein R₁, R₂, R₃ and R₄ may be each independently selected from the group including a hydrogen atom; a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃ and R₄ is a hydrolysable functional group;

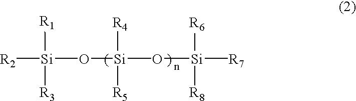

wherein R₁, R₂, R₃, R₄, R₅, R₆, R₇ and R₈ may be each independently selected from the group including a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃, R₄, R₅, R₆, R₇ and R₈ is a hydrolysable functional group, and n is an integer from 0 to 50; and

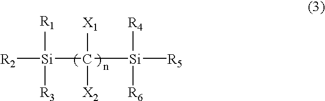

wherein R₁, R₂, R₃, R₄, R₅ and R₆ may be each independently selected from the group including a hydrogen atom, a hydroxyl group, a halogen atom; substituted and unsubstituted C₁-C₂₀ alkyl groups, substituted and unsubstituted C₂-C₂₀ alkenyl groups, substituted and unsubstituted C₂-C₂₀ alkynyl groups; substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃, R₄, R₅ and R₆ is a hydrolysable functional group, X₁ and X₂ may be each independently selected from the group including a halogen atom, substituted and unsubstituted C₁-C₂₀ alkoxy groups, and substituted and unsubstituted C₆-C₂₀ aryloxy groups, and n is an integer from 0 to 50.

The organosilane compound used to prepare the hybrid polymer according to example embodiments of the present invention may be selected from compounds represented by Formulae 4 to 6 below:

SiX₁X₂X₃X₄ (4)

wherein X₁, X₂, X₃ and X₄ may be each independently a halogen atom, substituted and unsubstituted C₁-C₂₀ alkoxy groups and substituted and unsubstituted C₆-C₂₀ aryloxy groups, with the proviso that at least one of X₁, X₂, X₃ and X₄ is a hydrolysable functional group;

R₁SiX₁X₂X₃ (5)

wherein X₁, X₂ and X₃ may be each independently a halogen atom, substituted and unsubstituted C₁-C₂₀ alkoxy groups, and substituted and unsubstituted C₆-C₂₀ aryloxy groups, with the proviso that at least one of X₁, X₂, X₃ and X₄ is a hydrolysable functional group, and R₁ may be selected from the group including a hydrogen atom, a hydroxyl group, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups, and substituted and unsubstituted C₆-C₂₀ aryloxy groups; and

R₁R₂SiX₁X₂ (6)

wherein X₁ and X₂ may be each independently a halogen atom, substituted and unsubstituted C₁-C₂₀ alkoxy groups, and substituted and unsubstituted C₆-C₂₀ aryloxy groups, with the proviso that at least one of X₁ and X₂ is a hydrolysable functional group, and R₁ and R₂ may be each independently selected from the group including a hydrogen atom, a hydroxyl group, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups.

The organosilane compound may be a mixture of the compounds of Formulae 4 to 6.

The term “substituted” as used in Formulae 1 to 6 means that the groups may be substituted with acryl, amino, hydroxyl, carboxyl, aldehyde, epoxy, nitrile, and/or other groups.

The organic-inorganic hybrid material used to prepare the hybrid polymer of the present invention may refer to a polymer prepared by hydrolysis and/or condensation of the organosilane compound in an organic solvent. The organic solvent may be in the presence of water and/or an acid or base catalyst. Examples of preferred acid and base catalysts that can be used for the hydrolysis and condensation may include hydrochloric acid, nitric acid, benzene sulfonic acid, oxalic acid, formic acid, potassium hydroxide, sodium hydroxide, triethylamine, sodium bicarbonate and/or pyridine. The molar ratio of the organosilane compound to the catalyst may be in the range of about 1:0.000001 to about 1:10. The molar ratio of the organosilane compound to water may be in the range of approximately 1:1 to 1:1000.

The preparation of the organic-inorganic hybrid polymer according to example embodiments of the present invention is depicted by Reaction Scheme 1 below:

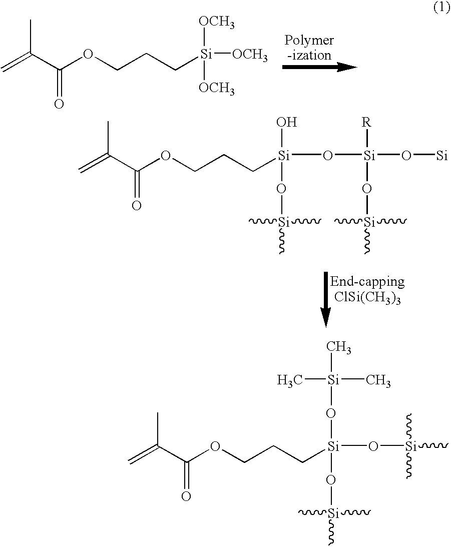

As depicted in Reaction Scheme 1, a silanol moiety having a terminal hydroxyl group may not participate in an intermolecular network in the organic-inorganic hybrid material, which is a polymerization product of the organosilane compound. An organic-inorganic hybrid polymer prepared by capping terminal hydroxyl groups of silanol moieties remaining in the organic-inorganic hybrid material with the compound represented by any one of Formulae 1 to 3 may be provided.

The compounds of Formulae 1 to 3 used as capping agents may be silane compounds including at least one hydrolysable functional groups. The compounds of Formulae 1 to 3 used as capping agents may cap terminal hydroxyl groups remaining in the organic-inorganic hybrid material. Generation of electrical hysteresis in conventional organic insulators using Si polymers may present problems in driving displays. Because the capped organic-inorganic hybrid polymer reduces the content of hydroxyl groups remaining therein, the cause of hysteresis may be removed. As a result, the organic-inorganic hybrid polymer may decrease the hysteresis to less than 10 V, which may be more suitable for driving displays.

Examples of the silane compound used to cap terminal hydroxyl groups remaining in the organic-inorganic hybrid material include, but are not limited to silane compounds (e.g., chlorotrimethylsilane, chloroethyldimethylsilane, chlorodimethylvinylsilane, methoxytrimethylsilane, ethylmethoxydimethylsilane, methoxydimethylvinylsilane, dichlorodimethylsilane, dichloroethylmethylsilane, dichloromethylvinylsilane, dimethoxydimethylsilane and/or dimethoxymethylvinylsilane), siloxane compounds (e.g. 1,3-dichloro-1,1,3,3-tetramethyldisiloxane and 1,3-dimethoxy-1,1,3,3-tetramethyldisiloxane), and/or silanyl-substituted compounds (e.g. bis(chlorodimethylsilanyl)methane, bis(dimethoxymethylsilanyl)methane, bis(dichloromethylsilanyl)methane and bis(methoxydimethylsilanyl)methane).

Other example embodiments of the present invention are directed to an organic insulator composition (hereinafter interchangeably referred to as ‘organic insulator’) including the organic-inorganic hybrid polymer, an organometallic compound and/or an organic solvent.

Organometallic compounds that may be used in the organic insulator composition include compounds having increased insulating properties and/or higher dielectric constant (e.g., metal oxides having a dielectric constant of 4 or higher). At least one compound selected from titanium, zirconium, hafnium and/or aluminum compounds may be used as the organometallic compound. Non-limiting example examples of the organometallic compound include titanium compounds (e.g., titanium (IV) n-butoxide, titanium (IV) t-butoxide, titanium (IV) ethoxide, titanium (IV) 2-ethylhexoxide, titanium (IV) isopropoxide, titanium (IV) (diisopropoxide) bis(acetylacetonate), titanium (IV) oxide bis(acetylacetonate), trichlorotris(tetrahydrofuran)titanium (III), tris(2,2,6,6-tetramethyl-3,5-heptanedionato)titanium (III), (trimethyl)pentamethyl cyclopentadienyltitanium (IV), pentamethylcyclopentadienyltitanium trichloride (IV), pentamethylcyclopentadienyltitanium trimethoxide (IV), tetrachlorobis(cyclohexylmercapto)titanium (IV), tetrachlorobis(tetrahydrofuran)titanium (IV), tetrachlorodiamminetitanium (IV), tetrakis(diethylamino)titanium (IV), tetrakis(dimethylamino)titanium (IV), bis(t-butylcyclopentadienyl)titanium dichloride, bis(cyclopentadienyl)dicarbonyl titanium (II), bis(cyclopentadienyl)titanium dichloride, bis(ethylcyclopentadienyl)titanium dichloride, bis(pentamethylcyclopentadienyl)titanium dichloride, bis(isopropylcyclopentadienyl)titanium dichloride, tris(2,2,6,6-tetramethyl-3,5-heptanedionato)oxotitanium (IV), chlorotitanium triisopropoxide, cyclopentadienyltitanium trichloride, dichlorobis(2,2,6,6-tetramethyl-3,5-heptanedionato)titanium (IV), dimethylbis(t-butylcyclopentadienyl)titanium (IV) and/or di(isopropoxide)bis(2,2,6,6-tetramethyl-3,5-heptanedionato)titanium (IV)); zirconium compounds (e.g., zirconium (IV) n-butoxide, zirconium (IV) t-butoxide, zirconium (IV) ethoxide, zirconium (IV) isopropoxide, zirconium (IV) n-propoxide, zirconium (IV) acetylacetonate, zirconium (IV) hexafluoroacetylacetonate, zirconium (IV) trifluoroacetylacetonate, tetrakis(diethylamino)zirconium, tetrakis(dimethylamino)zirconium, tetrakis(2,2,6,6-tetramethyl-3,5-heptanedionato)zirconium (IV) and/or zirconium (IV) sulfate tetrahydrate); hafnium compounds (e.g., hafnium (IV) n-butoxide, hafnium (IV) t-butoxide, hafnium (IV) ethoxide, hafnium (IV) isopropoxide, hafnium (IV) isopropoxide monoisopropylate, hafnium (IV) acetylacetonate and/or tetrakis(dimethylamino)hafnium) and/or aluminum compounds (e.g., aluminum n-butoxide, aluminum t-butoxide, aluminum sec-butoxide, aluminum ethoxide, aluminum isopropoxide, aluminum acetylacetonate, aluminum hexafluoroacetylacetonate, aluminum trifluoroacetylacetonate and/or tris(2,2,6,6-tetramethyl-3,5-heptanedionato)aluminum).

The organometallic compound in the organic insulator composition may be from 0.01 to 20 parts-by-weight, based on 100 parts-by-weight of the organic-inorganic hybrid polymer. When the organometallic compound is less than 0.01 parts-by-weight, addition of the organometallic compound may have minimal or no effect. When the organometallic compound is 20 parts-by-weight or greater, the composition may become heterogeneous and/or a leakage current of a device using the composition may undesirable increase.

Any organic solvent, which is commonly used or known in the art to produce an organic insulating film, may be used in the organic insulator composition The organic solvent may include aliphatic hydrocarbon solvents (e.g., hexane and heptane), aromatic hydrocarbon solvents (e.g., toluene, pyridine, quinoline, anisole, mesitylene and/or xylene), ketone-based solvents (e.g., cyclohexanone, methyl ethyl ketone, 4-heptanone, methyl isobutyl ketone, 1-methyl-2-pyrrolidinone, cyclohexanone and acetone), ether-based solvents (e.g., tetrahydrofuran and isopropyl ether), acetate-based solvents (e.g., ethyl acetate, butyl acetate and propylene glycol methyl ether acetate), alcohol-based solvents (e.g., isopropyl alcohol and butyl alcohol), amide-based solvents (e.g., dimethylacetamide and dimethylformamide), silicon-based solvents and/or mixtures thereof. The organic solvent may be 100 to 400 parts-by-weight, based on 100 parts of the organic-inorganic hybrid polymer.

The organic insulator composition may include a binder. The binder may be selected from the group including the compounds of Formulae 1 to 6 and polymers thereof, polyvinyl acetal and derivatives thereof, polyvinyl alcohol and derivatives thereof, polyvinyl phenol and derivatives thereof, polyacryl and derivatives thereof, polynorbornene and derivatives thereof, polyethylene glycol derivatives, polypropylene glycol derivatives, polysiloxane derivatives, cellulose derivatives, epoxy resins, melamine resins, glyoxal and/or copolymers thereof. The polymers may include a polar group (e.g., a hydroxyl group, a carboxyl group or salt therof, a phosphoric acid group or salt thereof, a sulfonic acid group or salt thereof, and/or an amine group or salt thereof) at the terminal position of the backbone or side chains of the polymers.

The binder may be 0 to 10 parts-by-weight, based on 100 parts-by-weight of the organic-inorganic hybrid polymer. If the binder is more than 10 parts-by-weight, a more uniform thin film may not be formed.

The organic insulator may be coated on a substrate, followed by annealing to form an organic insulating layer. The application of the organic insulator to the substrate may be performed by various coating techniques. Coating techniques includes spin coating, dip coating, roll coating, screen coating, spray coating, spin casting, flow coating, screen printing, ink jet, drop casting and/or the like. To ease coating and apply a coating having a more uniform thickness, spin coating or printing may be used. When spin coating, the spin speed may be adjusted within the range of about 400 to 5,000 rpm.

The annealing may be performed by heating the coated substrate to a temperature of 50° C. or higher for one minute or longer.

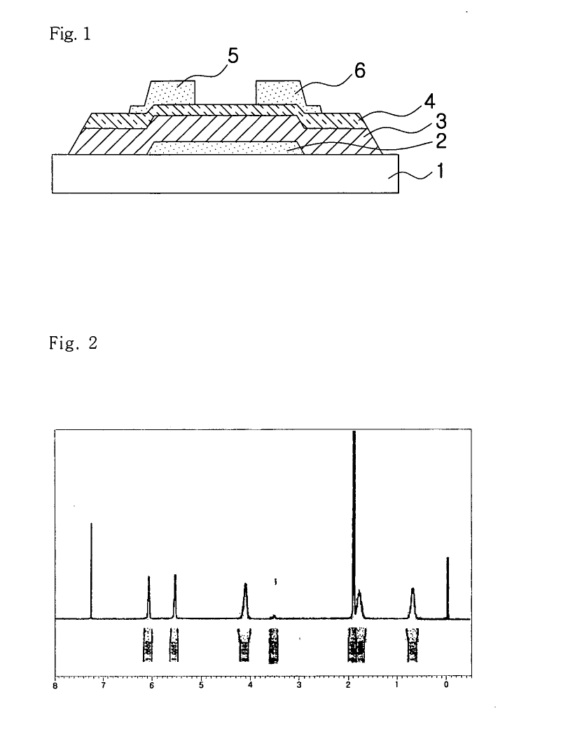

FIG. 1 is a diagram illustrating a cross-sectional view of an organic thin film transistor according to example embodiments of the present invention.

As shown in FIG. 1, the organic thin film transistor may include a substrate 1, a gate electrode 2, an organic insulating layer 3, an organic semiconductor layer 4 and/or source/drain electrodes 5 and 6. Those of ordinary skill in the art should appreciate modifications to the organic thin film transistor.

The substrate 1 may be formed of any material appreciated in the art. The substrate may be formed of a material including glass, silica and/or plastic.

The gate electrode 2 and the source/drain electrodes 5 and 6 may be formed of metals and/or electrically conductive polymers commonly used in the art. The metals and/or electrically conductive polymers may include doped silicon (Si), and metals (e.g. gold (Au), silver (Ag), aluminum (Al), copper (Cu), nickel (Ni), chromium (Cr), molybdenum (Mo), tungsten (W) and/or indium tin oxide (ITO)). After the substrate is washed to remove impurities present thereon, the metal may be deposited thereon by any technique known in the art (e.g., chemical vapor deposition, plasma chemical vapor deposition and/or sputtering) followed by patterning to form the gate electrode.

As explained above, the organic insulating layer 3 may be formed by spin-coating the organic insulator according to a solution process, followed by curing.

The organic semiconductor layer 4 may be formed from materials that include, but are not limited to, pentacene, polythiophene, polyaniline, polyacetylene, polypyrrole, polyphenylene vinylene and/or derivatives thereof.

When the organic insulator is used to form an organic insulating layer of an organic thin film transistor, unit characteristics of the organic thin film transistor may be increased. An organic thin film transistor using the organic insulator composition according to example embodiments of the present invention may be more effectively used in the manufacture of a variety of electronic devices (e.g., liquid crystal displays (LCDs), photovoltaic devices, organic light-emitting devices (OLEDs), sensors, memory devices and integrated circuits).

Hereinafter, the example embodiments will be described in detail with reference to the following examples. However, these examples are given for the purpose of illustration and are not to be construed as limiting the scope of the embodiments.

### PREPARATIVE EXAMPLE 1

### Synthesis of Organic-Inorganic Hybrid Polymer

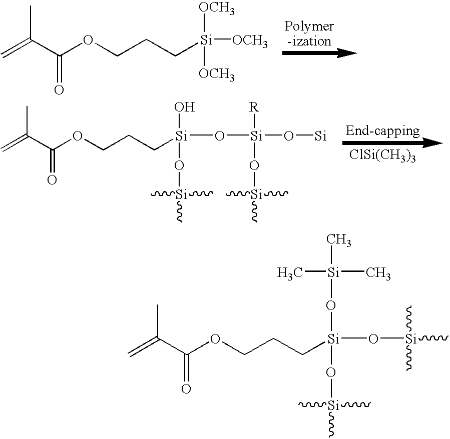

20 g (80.531 mmol) of methacryloxypropyltrimethoxysilane (‘MAPTMS’) was placed into a flask, and 3.5 ml of a hydrochloric acid (HCl) solution (0.001021 moles of hydrochloride per 1 cc of water) in metal ion-free water (deionized (D.I.) water) was added thereto. After the mixture was allowed to react at room temperature for about 30 minutes, the reaction was quenched by the addition of 100 ml of tetrahydrofuran and 100 ml of diethyl ether. The reaction solution was transferred to a separatory funnel, washed with water (approximately 30 ml) three times and evaporated at reduced pressure to remove volatile materials. A viscous polymer as a colorless liquid remained. The polymer was dissolved in 15 ml of ethyl acetate. The solution was passed through a filter, having a pore size of 0.2 μm, to remove fine powder and other impurities contained therein. Clean portions of the filtrate were collected and placed under reduced pressure to remove (or evaporate) volatile materials, yielding approximately 13 g of a viscous MAPTMS polymer as a colorless liquid.

12 g of the MAPTMS polymer was mixed with 10 mL of THF, followed by the addition of 61 mL of chlorotrimethylsilane. The mixture was stirred at room temperature for about 24 hours. The resulting solution was diluted in ethyl acetate, washed with water three times and stirred in a 1 N NAOH solution for about 3 hours. The mixture was washed with water four times, dried over MgSO₄, distilled at reduced pressure and dried under vacuum, yielding approximately 13 g of a sticky oil.

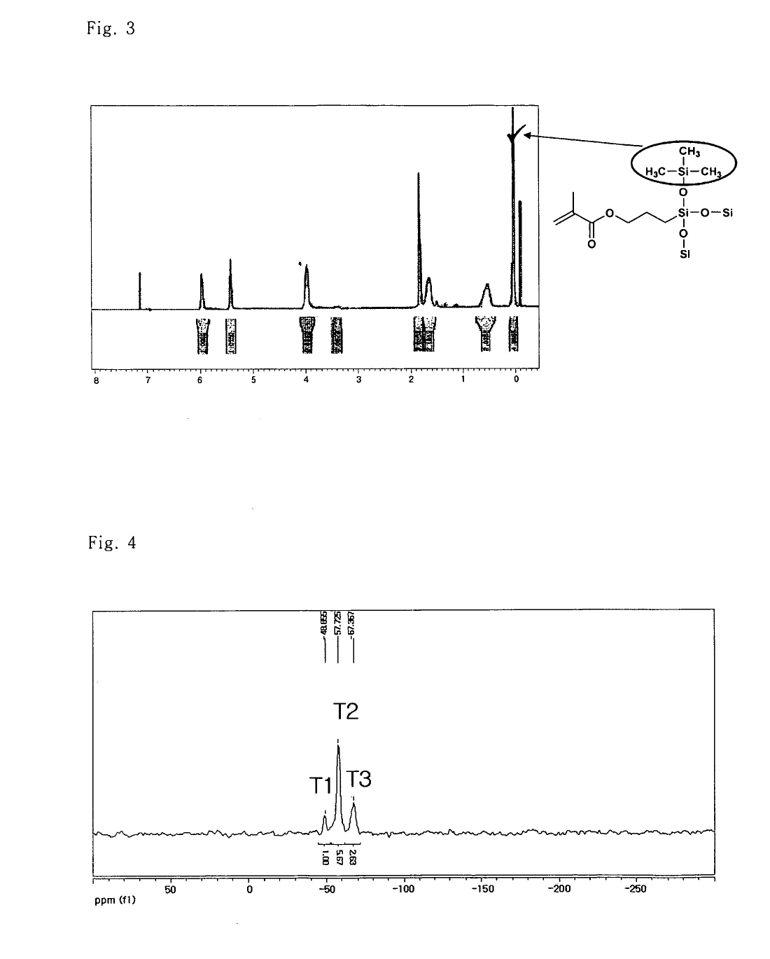

FIG. 2 is a ¹H-NMR spectrum of an organic-inorganic hybrid polymer prepared prior to capping in Preparative Example 1 according to example embodiments of the present invention. FIG. 3 is a ¹H-NMR spectrum of an organic-inorganic hybrid polymer prepared after capping in Preparative Example 1 according to example embodiments of the present invention.

As shown in the spectra of FIGS. 2 and 3, a peak corresponding to —Si(CH₃)₃ appears by capping of the hybrid polymer with chlorotrimethylsilane.

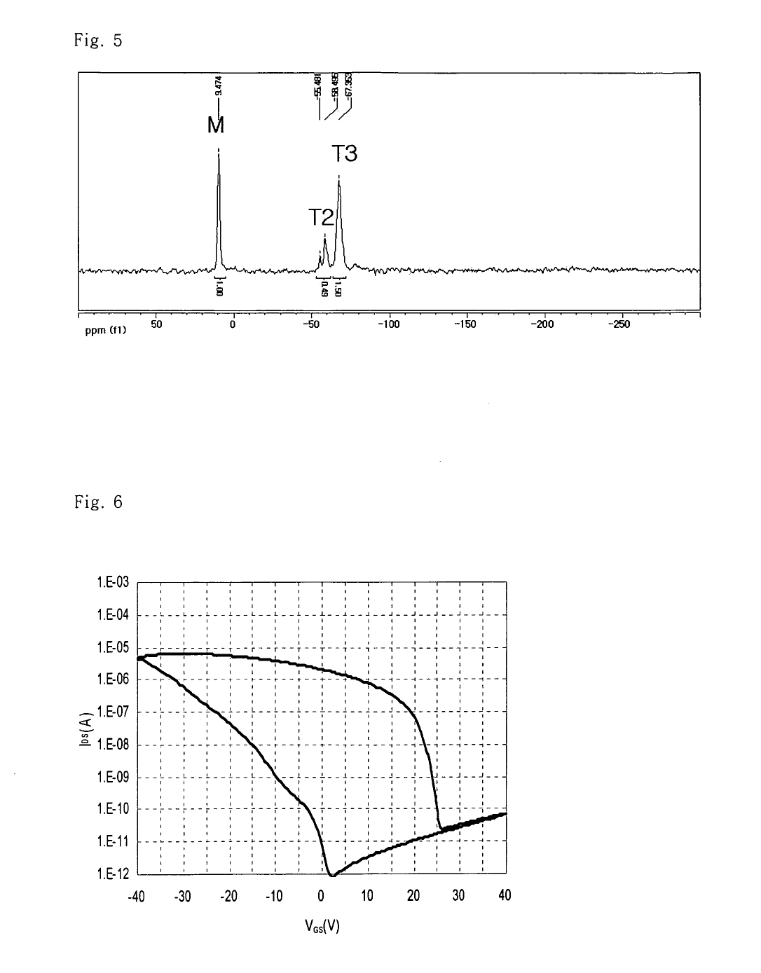

FIG. 4 is a ²⁹Si-NMR spectrum of an organic-inorganic hybrid polymer prepared prior to capping in Preparative Example 1 according to example embodiments of the present invention. FIG. 5 is a ²⁹Si-NMR spectrum of an organic-inorganic hybrid polymer prepared after capping in Preparative Example 1 according to example embodiments of the present invention.

Referring to FIGS. 4 and 5, the content of the silanol moieties (Si—OH) remaining in the MAPTMS polymer is about 71.7% before end-capping, (calculated by the equation (T₁+T₂)/T₃). The content of the silanol moieties (Si—OH) is about 24.6% after end-capping. As such, when the structure T₂ is rapidly changed to the structure T₃ by end-capping, the amount of the silanol moieties may be decreased. The amount of the silanol moieties may significantly decrease.

T₁ represents (RSiO)Si(OH)₂, T₂ represents (RSiO)₂Si(OH), T₃ represents (RSiO)₃Si and M represents SiR′₃.

### EXAMPLE 1

### Fabrication of Organic Thin Film Transistor

The organic-inorganic hybrid polymer prepared in Preparative Example 1, titanium t-butoxide and polyvinyl butyral were mixed in a ratio of 100:15:1.4. The mixed polymer was dissolved in 300 parts-by-weight of butanol to prepare an organic insulator composition.

Aluminum was deposited on a clean glass substrate to form an gate electrode having a thickness of 800 Å. The organic insulator composition prepared in Preparative Example 1 was spin-coated to a thickness of about 8,000 Å thereon at approximately 2,000 rpm and baked at 100° C. for one hour to form an organic insulating layer. Pentacene was deposited to a thickness of 700 Å on the organic insulating layer by vacuum deposition to form an organic semiconductor layer. Source/drain gold (Au) electrodes with a channel length of 100 μm and a channel width of 1 mm, were formed on the organic semiconductor layer. The source/drain electrodes were formed having thickness of 500 Å. The resulting structure of the transistor is shown in FIG. 1.

### COMPARATIVE EXAMPLE 1

An organic thin film transistor was fabricated in the same manner as described in Example 1 except that the MAPTMS polymer having uncapped terminal hydroxyl groups of silanol moieties in Preparative Example 1 was used to form an organic insulating layer.

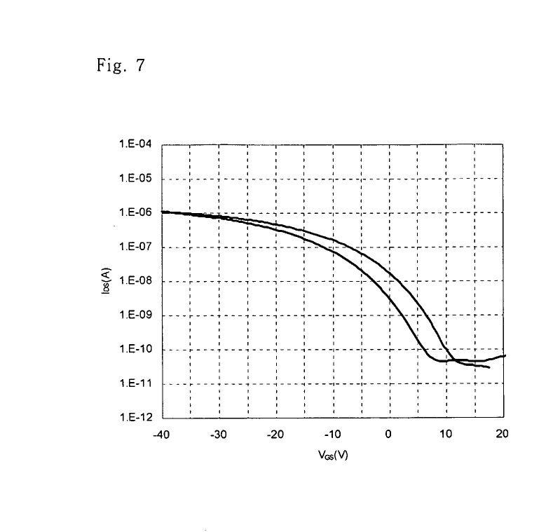

To evaluate the electrical properties of the organic thin film transistors fabricated in Example 1 and Comparative Example 1, the current transfer characteristics of the devices were measured using a KEITHLEY Semiconductor Characterization System (4200-SCS). The results obtained are shown in FIGS. 6 and 7.

FIG. 6 is a graph showing the current transfer characteristics of an organic thin film transistor fabricated in Comparative Example 1 as a function of gate voltage according to example embodiments of the present invention. FIG. 7 is a graph showing the current transfer characteristics of an organic thin film transistor fabricated in Comparative Example 1 as a function of gate voltage according to example embodiments of the present invention.

As shown in FIGS. 6 and 7, the organic thin film transistor fabricated by using the polymer containing uncapped terminal hydroxyl groups exhibits a hysteresis of about 30V or more whereas the organic thin film transistor using the organic insulating composition of the present invention exhibits a hysteresis of less than about 10V.

The method used to derive the threshold voltage and hysteresis values of the organic thin film transistors, as calculated in FIGS. 6 and 7, will now be described in detail.

### Threshold Voltage (V_{T})

A graph representing the relationship between (I_{SD})^{1/2} and V_{G} was produced using the Equations 1-4 in the saturation region:

$$\begin{matrix}{I}_{SD} = \frac{W {C}_{0}}{2 L} {μ ( {V}_{G} - {V}_{T} )}^{2} & Equation 1 \\ \sqrt{{I}_{SD}} = \sqrt{\frac{μ {C}_{0} W}{2 L}} ( {V}_{G} - {V}_{T} ) & Equation 2 \\ slope = \sqrt{\frac{μ {C}_{0} W}{2 L}} & Equation 3 \\ {μ}_{FET} = {( slope )}^{2} \frac{2 L}{{C}_{0} W} & Equation 4\end{matrix}$$

In Equations 1-4, I_{SD} represents the source-drain current, μ and μ_{FET} represent the charge carrier mobility, Cₒ represents the capacitance of the oxide film, W represents the: channel width, L represents the channel length, V_{G} represents the gate voltage and V_{T} represents the threshold voltage.

The threshold voltage (V_{T}) was obtained from the intersection between the V_{G} axis and the extension line of the linear portion in the graph of (I_{SD})^{1/2} versus V_{G}. As the absolute value of the threshold voltage approaches zero, the consumption of electric power decreases.

### Hysteresis

The hysteresis was calculated from a difference in threshold voltage between the forward sweep and the backward sweep. The results are shown in Table 1 below.

TABLE 1

| Example No. | Threshold voltage (V_{T}) | Hysteresis (V) |
|---|---|---|
| Example 1 | 1 | 5 |
| Comparative Example 1 | 19.5 | 44.5 |

As shown in Table 1, the organic thin film transistor using the organic insulator composition according to example embodiments of the present invention exhibits increased electrical insulating properties and physical properties (e.g., low threshold voltage and low hysteresis) while maintaining driving characteristics (e.g., charge carrier mobility).

As apparent from the foregoing, terminal hydroxyl groups of silanol moieties of an organic-inorganic hybrid material are capped with an organosilane compound in the organic-inorganic hybrid polymer according to example embodiments of the present invention. When the organic-inorganic hybrid polymer according to example embodiments of the present invention are used to form an insulating layer of an organic thin film transistor, the hysteresis and threshold voltage characteristics of the organic thin film transistor increase. As such, an organic thin film transistor using the organic-inorganic hybrid polymer of according to example embodiments of the present invention may be more effectively used in the manufacture of electronic devices (e.g. liquid crystal displays (LCDs), photovoltaic devices, organic light-emitting devices (OLEDs), sensors, memory devices and integrated circuits).

The foregoing is illustrative of example embodiments of the present invention and is not to be construed as limiting thereof. Although a few example embodiments of the present invention have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. An organic-inorganic hybrid polymer prepared by capping terminal hydroxyl groups of an organic-inorganic hybrid material, which is a hydrolysis and condensation product of an organosilane compound, with a compound represented by any one of Formulae 1 to 3 below: 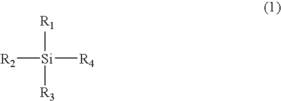
wherein R₁, R₂, R₃ and R₄ are each independently selected from the group consisting of a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃ and R₄ is a hydrolysable functional group; 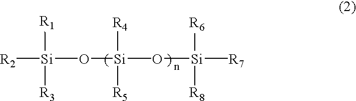
wherein R₁, R₂, R₃, R₄, R₅, R₆, R₇ and R₈ are each independently selected from the group consisting of a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃, R₄, R₅, R₆, R₇ and R₈ is a hydrolysable functional group, and
n is an integer from 0 to 50; and 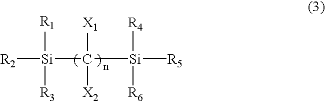
wherein R₁, R₂, R₃, R₄, R₅ and R₆ are each independently selected from the group consisting of a hydrogen atom, a hydroxyl group, a halogen atom, substituted and unsubstituted C₁-C₂₀ alkyl groups, substituted and unsubstituted C₂-C₂₀ alkenyl groups, substituted and unsubstituted C₂-C₂₀ alkynyl groups; substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups, with the proviso that at least one of R₁, R₂, R₃, R₄, R₅ and R₆ is a hydrolysable functional group,
X₁ and X₂ are each independently selected from the group consisting of a halogen atom, substituted and unsubstituted C₁-C₂₀ alkoxy groups, and substituted and unsubstituted C₆-C₂₀ aryloxy groups, and
n is an integer from 0 to 50.

2. The polymer according to claim 1, wherein the silane compound represented by any one of Formulae 1 to 3 is at least one compound selected from the group consisting of chlorotrimethylsilane, chloroethyldimethylsilane, chlorodimethylvinylsilane, methoxytrimethylsilane, ethylmethoxydimethylsilane, methoxydimethylvinylsilane, dichlorodimethylsilane, dichloroethylmethylsilane, dichloromethylvinylsilane, dimethoxydimethylsilane, dimethoxymethylvinylsilane, 1,3-dichloro-1,1,3,3-tetramethyldisiloxane, 1,3-dimethoxy-1,1,3,3-tetramethyldisiloxane, bis(chlorodimethylsilanyl)methane, bis(dimethoxymethylsilanyl)methane, is(dichloromethylsilanyl)methane and bis(methoxydimethylsilanyl)methane.

3. The polymer according to claim 1, wherein the organosilane compound is at least one compound selected from compounds represented by Formulae 4 to 6 below:
SiX₁X₂X₃X₄ (4)
wherein X₁, X₂, X₃ and X₄ are each independently a halogen atom, substituted and unsubstituted C₁-C₂₀ alkoxy groups, and substituted and unsubstituted C₆-C₂₀ aryloxy groups, with the proviso that at least one of X₁, X₂, X₃ and X₄ is a hydrolysable functional group;
R₁SiX₁X₂X₃ (5)
wherein X₁, X₂ and X₃ are each independently a halogen atom, substituted and unsubstituted C₁-C₂₀ alkoxy groups, and substituted and unsubstituted C₆-C₂₀ aryloxy groups, with the proviso that at least one of X₁, X₂, X₃ and X₄ is a hydrolysable functional group, and
R₁ is selected from the group consisting of a hydrogen atom, a hydroxyl group, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups; and
R₁R₂SiX₁X₂ (6)
wherein X₁ and X₂ are each independently a halogen atom, substituted and unsubstituted C₁-C₂₀ alkoxy groups and substituted and unsubstituted C₆-C₂₀ aryloxy groups, with the proviso that at least one of X₁ and X₂ is a hydrolysable functional group, and
R₁ and R₂ are each independently selected from the group consisting of a hydrogen atom; a hydroxyl group, substituted and unsubstituted C₁-C₂₀ alkyl groups, substituted and unsubstituted C₂-C₂₀ alkenyl groups, substituted and unsubstituted C₂-C₂₀ alkynyl groups, substituted and unsubstituted C₆-C₂₀ aryl groups, substituted and unsubstituted C₆-C₂₀ arylalkyl groups, substituted and unsubstituted C₁-C₂₀ alkoxy groups and substituted and unsubstituted C₆-C₂₀ aryloxy groups.

4. The polymer according to claim 3, wherein R₁ and R₂ are groups in which the hydrogen atoms covalently bonded to the carbon atoms are wholly or partly replaced by fluorine atoms.

5. An organic insulator composition, comprising:
the organic-inorganic hybrid polymer according to claim 3;
an organometallic compound; and
an organic solvent.

6. The composition according to claim 5, wherein the organometallic compound is at least one compound selected from titanium, zirconium, hafnium and aluminum compounds.

7. The composition according to claim 5, wherein the organometallic compound is selected from the group consisting of titanium (IV) n-butoxide, titanium (IV) t-butoxide, titanium (IV) ethoxide, titanium (IV) 2-ethylhexoxide, titanium (IV) isopropoxide, titanium (IV) (diisopropoxide) bis(acetylacetonate), titanium (IV) oxide bis(acetylacetonate), trichlorotris(tetrahydrofuran) titanium (III), tris(2,2,6,6-tetramethyl-3,5-heptanedionato) titanium (III), (trimethyl)pentamethyl cyclopentadienyltitanium (IV), pentamethylcyclopentadienyltitanium trichloride (IV), pentamethylcyclopentadienyltitanium trimethoxide (IV), tetrachlorobis(cyclohexylmercapto) titanium (IV), tetrachlorobis(tetrahydrofuran)titanium (IV), tetrachlorodiamminetitanium (IV), tetrakis(diethylamino)titanium (IV), tetrakis(dimethylamino)titanium (IV), bis(t-butylcyclopentadienyl)titanium dichloride, bis(cyclopentadienyl)dicarbonyl titanium (II), bis(cyclopentadienyl)titanium dichloride, bis(ethylcyclopentadienyl)titanium dichloride, bis(pentamethylcyclopentadienyl)titanium dichloride, bis(isopropylcyclopentadienyl)titanium dichloride, tris(2,2,6,6-tetramethyl-3,5-heptanedionato)oxotitanium (IV), chlorotitanium triisopropoxide, cyclopentadienyltitanium trichloride, dichlorobis(2,2,6,6-tetramethyl-3,5-heptanedionato)titanium (IV), dimethylbis(t-butylcyclopentadienyl)titanium (IV), di(isopropoxide)bis(2,2,6,6-tetramethyl-3,5-heptanedionato)titanium (IV), zirconium (IV) n-butoxide, zirconium (IV) t-butoxide, zirconium (IV) ethoxide, zirconium (IV) isopropoxide, zirconium (IV) n-propoxide, zirconium (IV) acetylacetonate, zirconium (IV) hexafluoroacetylacetonate, zirconium (IV) trifluoroacetylacetonate, tetrakis(diethylamino)zirconium, tetrakis(dimethylamino)zirconium, tetrakis(2,2,6,6-tetramethyl-3,5-heptanedionato)zirconium (IV), zirconium (IV) sulfate tetrahydrate, hafnium (IV) n-butoxide, hafnium (IV) t-butoxide, hafnium (IV) ethoxide, hafnium (IV) isopropoxide, hafnium (IV) isopropoxide monoisopropylate, hafnium (IV) acetylacetonate, tetrakis(dimethylamino)hafnium, aluminum n-butoxide, aluminum t-butoxide, aluminum sec-butoxide, aluminum ethoxide, aluminum isopropoxide, aluminum acetylacetonate, aluminum hexafluoroacetylacetonate, aluminum trifluoroacetylacetonate and tris(2,2,6,6-tetramethyl-3,5-heptanedionato)aluminum.

8. The composition according to claim 5, wherein the organic solvent is selected from the group consisting of aliphatic hydrocarbon solvents including hexane and heptane; aromatic hydrocarbon solvents including toluene, pyridine, quinoline, anisole, mesitylene, and xylene; ketone-based solvents including cyclohexanone, methyl ethyl ketone, 4-heptanone, methyl isobutyl ketone, 1-methyl-2-pyrrolidinone, cyclohexanone and acetone; ether-based solvents including tetrahydrofuran and isopropyl ether; acetate-based solvents including ethyl acetate, butyl acetate and propylene glycol methyl ether acetate; alcohol-based solvents including isopropyl alcohol and butyl alcohol; amide-based solvents including dimethylacetamide and dimethylformamide; silicon-based solvents and mixtures thereof.

9. The composition according to claim 5, wherein the composition includes 100 parts-by-weight of the organic-inorganic hybrid polymer; 0.01 to 20 parts-by-weight of the organometallic compound; and 100 to 400 parts-by-weight of the organic solvent.

10. The composition according to claim 5, further comprising a binder.

11. The composition according to claim 10, wherein the binder is selected from the group consisting of the compounds of Formulae 1 to 6 and polymers thereof, polyvinyl acetal and derivatives thereof, polyvinyl alcohol and derivatives thereof, polyvinyl phenol and derivatives thereof, polyacryl and derivatives thereof, polynorbornene and derivatives thereof, polyethylene glycol derivatives, polypropylene glycol derivatives, polysiloxane derivatives, cellulose derivatives, epoxy resins, melamine resins, glyoxal, and copolymers thereof.

12. The composition according to claim 10, wherein the binder is present in an amount of 0 to 10 parts-by-weight, based on 100 parts-by-weight of the organic-inorganic hybrid polymer.

13. An organic thin film transistor, comprising:
a substrate;
a gate electrode;
an organic insulating layer;
an organic semiconductor layer; and
source/drain electrodes;
wherein the organic insulating layer is formed of the organic insulator composition according to claim 5.

14. An electronic device, comprising the organic thin film transistor according to claim 13.

15. The electronic device according to claim 14, wherein the electronic device is a liquid crystal display (LCD), a photovoltaic device, an organic light-emitting device (OLED), a sensor, a memory device or an integrated circuit.

16. A method of synthesizing the organic-inorganic hybrid polymer, comprising:
capping terminal hydroxyl groups of an organic-inorganic hybrid material, wherein the organic-inorganic hybrid material is formed by hydrolyzing and condensing an organosilane compound derivative with the compound represented by any one of Formulae 1 to 3 according to claim 1.

17. The method of claim 16, wherein the hydroxyl groups are attached to silanol moieties, and the silanol moieties do not contribute to forming an intermolecular network of the organic-inorganic hybrid material.

18. A method of manufacturing the organic insulator composition, comprising:
forming the organic-inorganic hybrid polymer according to claim 16; and
mixing the organic-inorganic hybrid polymer with an organometallic compound and a solvent.

19. A method of the organic thin film transistor, comprising:
forming a substrate;
forming a gate electrode on the substrate;
forming an organic insulating layer coating the gate electrode, wherein the organic insulating layer is formed using the organic insulator composition formed according to claim 18;
annealing the organic insulating layer;
forming an organic semiconductor layer on the organic insulating layer; and
forming source/drain electrodes on the organic insulating layer.
